(19) United States
(12) Patent Application Publication
(10) Pub. No.: US 2025/0125229 A1
(43) Pub. Date: Apr. 17, 2025

(54) SEMICONDUCTOR DEVICE

(71) Applicant: SAMSUNG ELECTRONICS CO., LTD., Suwon-si (KR)

(72) Inventors: Taejun Jeon, Suwon-si (KR); Seunghwan Kim, Suwon-si (KR); Junwoo Park, Suwon-si (KR)

(21) Appl. No.: 18/731,878

(22) Filed: Jun. 3, 2024

(30) Foreign Application Priority Data
Oct. 16, 2023 (KR) 10-2023-0137975

(51) Int. Cl. H01L 23/495; H01L 23/00; H01L 23/29; H01L 23/373; H01L 23/498; H01L 25/065

(52) U.S. Cl. CPC H01L 23/49568; H01L 23/293; H01L 23/3736; H01L 23/49811; H01L 24/16; H01L 25/0655; H01L 2224/16188; H01L 2924/3511

(57) ABSTRACT

Provided is a semiconductor device including a tower-shaped or bridge-shaped connection structure and a metal plate. The semiconductor device includes: a package substrate; a semiconductor chip stacked on the package substrate along a vertical direction; a connection structure arranged on the package substrate and formed to surround a sidewall of the semiconductor chip; a metal plate attached to an upper surface of the connection structure; and a sealant formed to cover an upper surface of the semiconductor chip and contact with a side surface of the connection structure.

### CROSS-REFERENCE TO RELATED APPLICATION

This application claims priority under 35 U.S.C. § 119 to Korean Patent Application No. 10-2023-0137975, filed on Oct. 16, 2023, in the Korean Intellectual Property Office, the disclosure of which is incorporated by reference herein in its entirety.

### BACKGROUND

The present disclosure relates to a semiconductor device, and more particularly, to a semiconductor device including a heat dissipation member.

With the increase in storage capacity of semiconductor memories, electronic devices including semiconductor memory elements are required to be thin and light. In a small high-capacity semiconductor package, substantial heat is generated by a semiconductor chip arranged inside the semiconductor package, and thus, dissipation of heat to the outside of the semiconductor package is essential to ensure the operational stability and product reliability of the semiconductor package and an electronic device including the same.

### SUMMARY

The present disclosure provides a semiconductor device having mounted thereon a metal plate capable of effectively dissipating heat generated by a semiconductor chip.

In addition, the technical objectives of the present disclosure are not limited to those mentioned above, and other objectives will be clearly understood by those skilled in the art from the following descriptions.

To achieve the technical objectives, the present disclosure provides the following semiconductor devices.

According to an aspect of the present disclosure, a semiconductor device includes: a package substrate, a semiconductor chip arranged on the package substrate, a connection structure arranged on the package substrate and formed to surround a sidewall of the semiconductor chip, a metal plate attached to an upper surface of the connection structure, and a sealant formed to cover an upper surface of the semiconductor chip and to be in contact with a side surface of the connection structure.

According to another aspect of the present disclosure, a semiconductor device includes: a package substrate, a semiconductor chip arranged on the package substrate, a connection structure arranged parallel to and apart from the semiconductor chip, at a vertical level higher than an upper surface of the semiconductor chip, and having line patterns in a plan view, a metal plate formed to fill between the line patterns of the connection structure, and a sealant formed to cover a space between the metal plate, the connection structure, and the semiconductor chip and a space between the package substrate and the semiconductor chip.

According to another aspect of the present disclosure, a semiconductor device includes: a package substrate, a semiconductor chip arranged on the package substrate, a first connection structure arranged on the package substrate, surrounding at least one edge of a sidewall of the semiconductor chip, and having a height greater than a height of the semiconductor chip, a second connection structure formed to have a lower surface in contact with an upper surface of the first connection structure and to have line patterns in a plan view, a metal plate formed to fill between the line patterns of the second connection structure, and a sealant formed to cover a space between the first and second connection structures, the metal plate, and the semiconductor chip and a space between the package substrate and the semiconductor chip, wherein the first connection structure and the second connection structure are formed as a single body.

### BRIEF DESCRIPTION OF THE DRAWINGS

FIG. 1A is a vertical cross-sectional view schematically illustrating an example of a semiconductor device.

FIG. 1B is a vertical cross-sectional view schematically illustrating another example of a semiconductor device.

FIG. 1C is a vertical cross-sectional view schematically illustrating another example of a semiconductor device.

FIG. 1D is a vertical cross-sectional view schematically illustrating another example of a semiconductor device.

FIGS. 2A to 2F are cross-sectional views illustrating an example of a method of manufacturing a semiconductor device.

FIGS. 3A to 3C are horizontal cross-sectional views illustrating examples of arrangement patterns of a connection structure and a metal plate.

FIGS. 4A to 4E are cross-sectional views illustrating an example of a method of manufacturing a semiconductor device.

FIG. 5A is a horizontal cross-sectional view illustrating an example of an arrangement pattern of a connection structure and a metal plate.

FIGS. 5B and 5C are vertical cross-sectional views schematically illustrating another example of a semiconductor device.

The same reference numerals are used for the same components in the drawings, and redundant descriptions thereof will be omitted.

### DETAILED DESCRIPTION

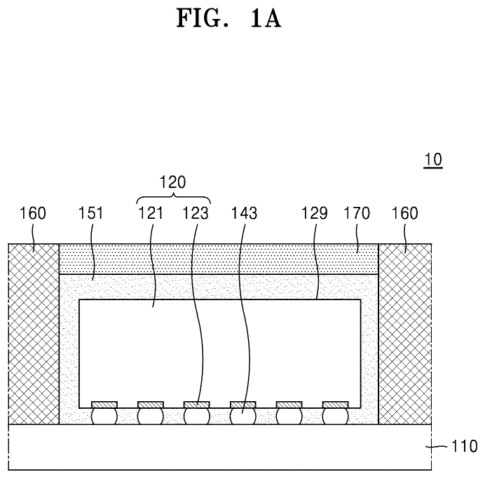

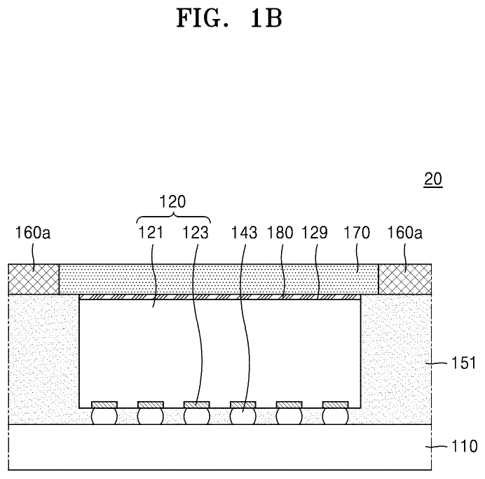

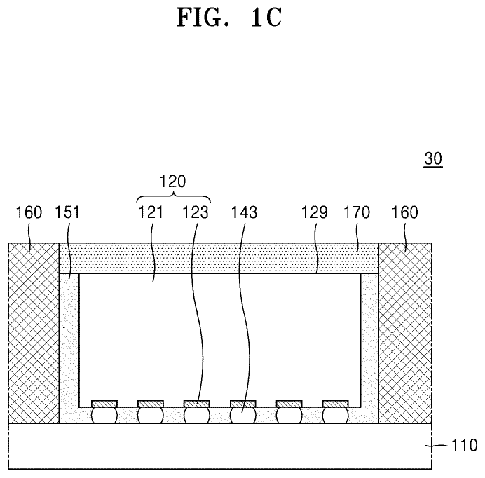

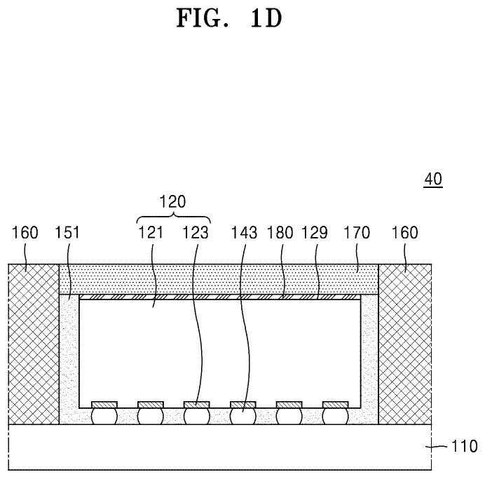

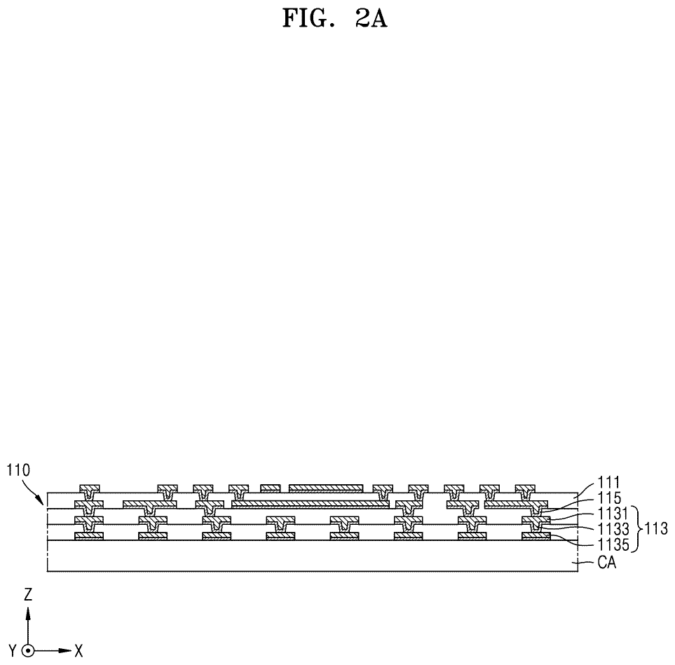

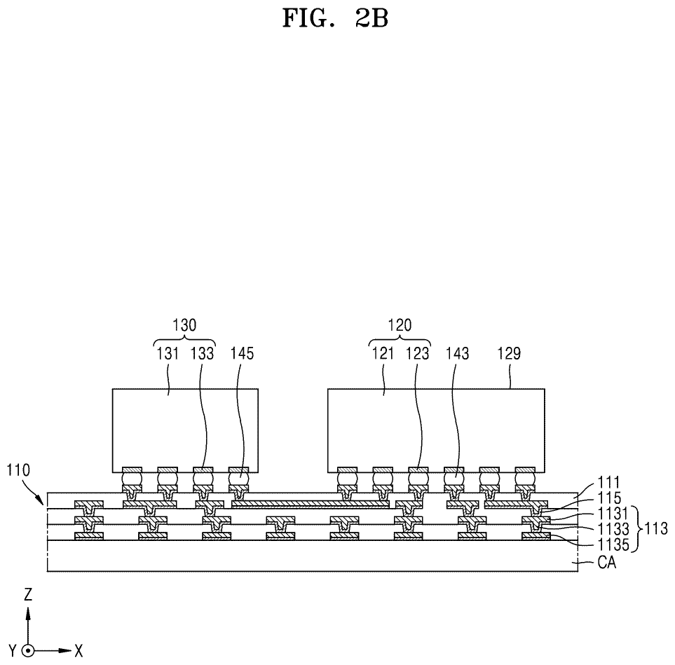

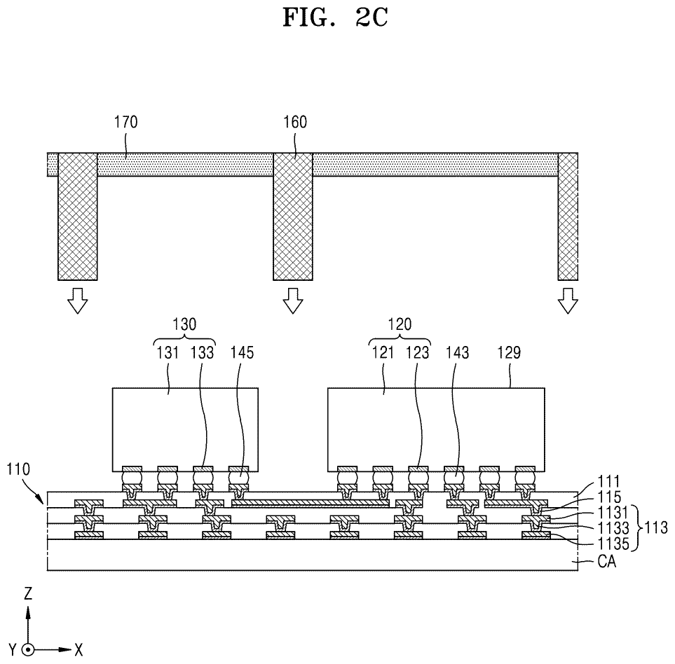

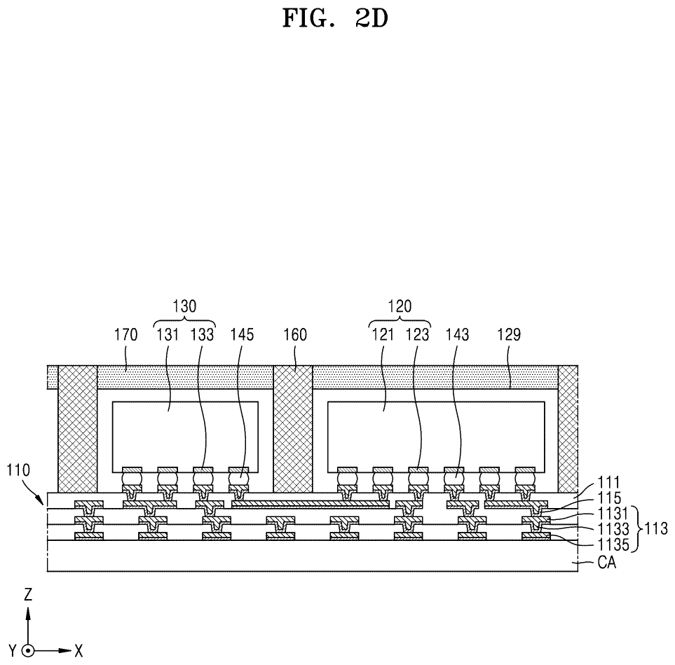

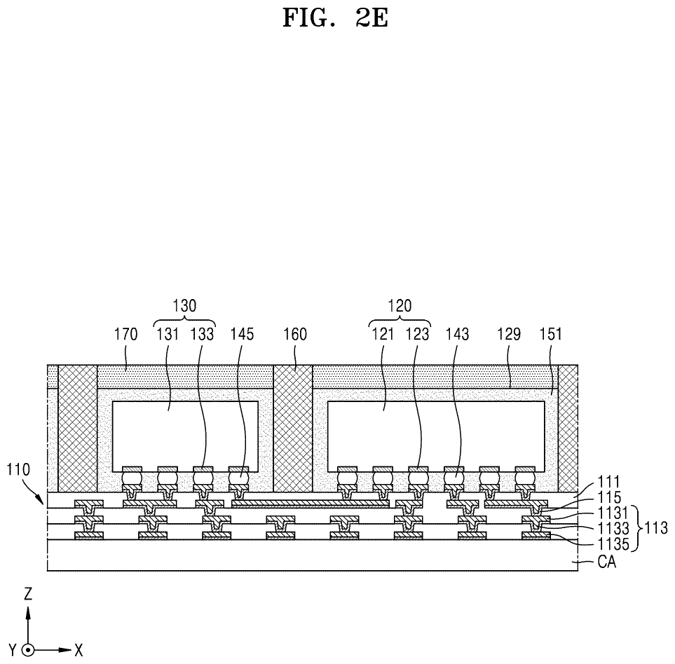

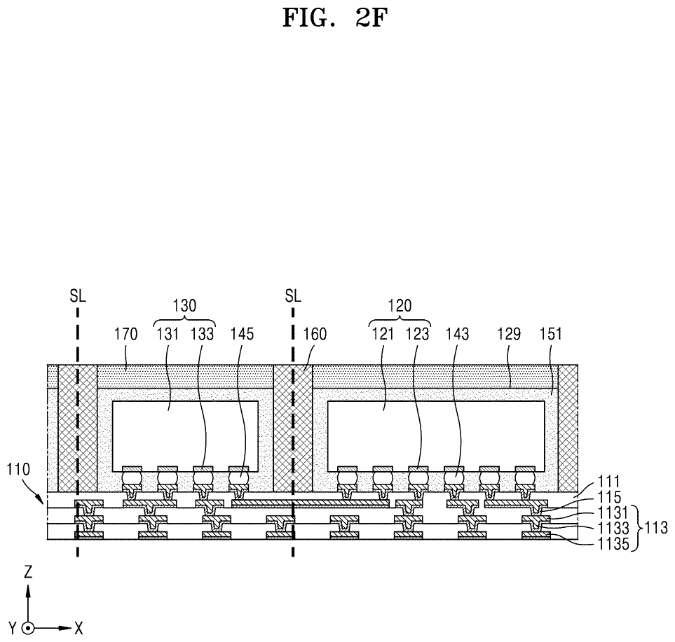

FIG. 1A is a vertical cross-sectional view schematically illustrating an example of a semiconductor device 10, and FIGS. 1B, 1C, and 1D are vertical cross-sectional views schematically and respectively illustrating examples of semiconductor devices 20, 30, and 40. FIGS. 2A to 2F are cross-sectional views illustrating a method of manufacturing the semiconductor device 10.

Components of the present disclosure will first be described with reference to FIGS. 1A to 1D and FIGS. 2A to 2F.

A first redistribution structure 110 may be a package substrate on which electronic components, such as a first semiconductor chip 120 and a second semiconductor chip 130, are mounted. The first redistribution structure 110 may generally have a flat plate shape or a panel shape. The first redistribution structure 110 may include upper and lower surfaces that are opposed to each other, and the upper and lower surfaces of the first redistribution structure 110 may each be substantially flat. Hereinafter, a horizontal direction (e.g., an X direction and/or a Y direction) is defined as a direction parallel to the upper or lower surface of the first redistribution structure 110, a vertical direction (e.g., a Z direction) is defined as a direction perpendicular to the upper or lower surface of the first redistribution structure 110, and a horizontal width is defined as a length in the horizontal direction (e.g., the X-direction and/or the Y-direction).

The first redistribution structure 110 includes a plurality of first redistribution insulating layers 111 and a first conductive redistribution pattern 113.

The plurality of first redistribution insulating layers 111 may be stacked on each other in the vertical direction (e.g., the Z direction). The plurality of first redistribution insulating layers 111 may include an insulating polymer, epoxy, or a combination thereof. For example, the plurality of first redistribution insulating layers 111 may each include a photo-imageable dielectric (PID) or photosensitive polyimide (PSPI).

The first conductive redistribution pattern 113 may include first conductive layers 1131, first conductive via patterns 1133, and external connection pads 1135. The first conductive layers 1131 may each extend in the horizontal direction (e.g., the X direction and/or the Y direction) and may be arranged at different vertical levels to form a multi-layer structure. The first conductive layers 1131 may be arranged on one of upper and lower surfaces of each of the plurality of first redistribution insulating layers 111. The first conductive layers 1131 may each include a line pattern extending in the form of a line along one of the upper and lower surfaces of each of the plurality of first redistribution insulating layers 111. The first conductive layer 1131 provided on an uppermost insulating layer of the plurality of first redistribution insulating layers 111 may include a pad to which a first chip connection bump 143 is attached for electrical connection with the first semiconductor chip 120, and a pad to which a second chip connection bump 145 is attached for electrical connection with the second semiconductor chip 130. The first conductive via patterns 1133 may extend in the vertical direction (e.g., the Z direction) through at least one layer of the plurality of first redistribution insulating layers 111. The first conductive via patterns 1133 may electrically connect the first conductive layers 1131 arranged at different vertical levels to each other or may electrically connect the first conductive layer 1131 and the external connection pad 1135 to each other. The external connection pads 1135 may be arranged on the lower surface of the first redistribution structure 110 and may be in contact with an external connection terminal (not shown). The external connection pads 1135 may be electrically connected to the first semiconductor chip 120 and/or the second semiconductor chip 130 through the first conductive redistribution pattern 113.

For example, the first conductive layers 1131, the first conductive via patterns 1133, and the external connection pads 1135 may each include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

At least some of the plurality of first conductive layers 1131 may be formed as a single body with some of the plurality of first conductive via patterns 1133. For example, some of the plurality of first conductive layers 1131 may be formed as a single body with the first conductive via patterns 1133 in contact with lower surfaces thereof. For example, the first conductive layer 1131 and the first conductive via pattern 1133 that are connected to each other may be formed together through an electroplating process.

In some implementations, each of the plurality of first conductive via patterns 1133 may have a tapered shape in which a horizontal width thereof narrows from an upper side to a lower side thereof. The horizontal width of each of the plurality of first conductive via patterns 1133 may gradually decrease toward an upper surface of the external connection pad 1135.

A seed metal layer 115 may be arranged between the first conductive layer 1131 and the first redistribution insulating layer 111 and between the first conductive via pattern 1133 and the first redistribution insulating layer 111. In addition, the seed metal layer 115 may be arranged between the first conductive via pattern 1133 and the external connection pad 1135. In addition, the seed metal layer 115 may be arranged between the external connection pad 1135 and an external connection terminal (not shown) and may extend along a lower surface of the external connection pad 1135. For example, the seed metal layer 115 may include at least one of Cu, Ti, titanium tungsten (TiW), titanium nitride (TiN), Ta, tantalum nitride (TaN), chromium (Cr), and Al. For example, the seed metal layer 115 may be formed through a physical vapor deposition process, such as sputtering.

In some implementations, the external connection pad 1135 may have a rectangular shape in a cross-sectional view. In some implementations, the lower surface of the external connection pad 1135 may be on the same plane as the lower surface of the first redistribution insulating layer 111. For example, the external connection pad 1135 may be formed through an electroplating process. In some implementations, the external connection pad 1135 may include a plurality of metal layers stacked in the vertical direction (e.g., the Z direction).

External connection terminals (not shown) may be attached to the external connection pads 1135 of the first redistribution structure 110. The external connection terminals may be configured to electrically and physically connect the first redistribution structure 110 and an external device to each other. The external connection terminals may be formed from, for example, solder balls or solder bumps.

The first semiconductor chip 120 may include a first semiconductor substrate 121 and a first chip pad 123. The first semiconductor substrate 121 may include upper and lower surfaces that are opposed to each other. The lower surface of the first semiconductor substrate 121 may be an active surface of the first semiconductor substrate 121, and the upper surface of the first semiconductor substrate 121 may be an inactive surface of the first semiconductor substrate 121. The first semiconductor substrate 121 may be formed from a semiconductor wafer. The first semiconductor substrate 121 may include, for example, silicon (Si). Alternatively, the first semiconductor substrate 121 may include a semiconductor element, such as germanium (Ge), or a compound semiconductor, such as silicon carbide (SiC), gallium arsenide (GaAs), indium arsenide (InAs), and indium phosphide (InP). The first semiconductor substrate 121 may include a conductive region, for example, an impurity-doped well or an impurity-doped structure. A semiconductor element layer including individual elements may be provided on the active surface of the first semiconductor substrate 121. The individual elements may include, for example, transistors. The individual elements may include microelectronic elements, for example, a metal-oxide-semiconductor field effect transistor (MOSFET), a system large scale integration (LSI), an image sensor such as a complementary metal-oxide-semiconductor (CMOS) imaging sensor (CIS), a micro-electro-mechanical system (MEMS), an active element, a passive element, and the like. The first chip pad 123 may be provided on a lower surface of the first semiconductor chip 120 and may be electrically connected to the individual elements of the semiconductor element layer.

The first semiconductor chip 120 may be mounted on the first redistribution structure 110 by a flip chip method. The first semiconductor chip 120 may be electrically and physically connected to the first conductive redistribution pattern 113 of the first redistribution structure 110 through the first chip connection bumps 143. The first chip connection bumps 143 may each be arranged between the first chip pad 123 of the first semiconductor chip 120 and the first conductive layer 1131 provided on the uppermost insulating layer of the first redistribution insulating layers 111. The first chip connection bumps 143 may include solder bumps.

The second semiconductor chip 130 may be electrically connected to the first semiconductor chip 120 through the first conductive redistribution pattern 113 of the first redistribution structure 110. The second semiconductor chip 130 may include a second semiconductor substrate 131 and a second chip pad 133. A lower surface of the second semiconductor substrate 131 may be an active surface of the second semiconductor substrate 131, and an upper surface of the second semiconductor substrate 131 may be an inactive surface of the second semiconductor substrate 131. A material of the second semiconductor substrate 131 may be substantially the same as or similar to a material of the first semiconductor substrate 121 of the first semiconductor chip 120. A semiconductor element layer including individual elements may be provided on the lower surface of the second semiconductor substrate 131. The second chip pad 133 may be provided on a lower surface of the second semiconductor chip 130 and may be electrically connected to the individual elements of the semiconductor element layer of the second semiconductor chip 130.

The second semiconductor chip 130 may be mounted on the first redistribution structure 110 by a flip chip method. The second semiconductor chip 130 may be electrically and physically connected to the first conductive redistribution pattern 113 of the first redistribution structure 110 through the second chip connection bumps 145. The second chip connection bumps 145 may each be arranged between the second chip pad 133 of the second semiconductor chip 130 and the first conductive layer 1131 provided on the uppermost insulating layer of the first redistribution insulating layers 111. The second chip connection bumps 145 may include solder bumps.

A sealant 151 may be arranged on the first redistribution structure 110 and may mold the first semiconductor chip 120 and the second semiconductor chip 130. The sealant 151 may cover the upper surface of the first redistribution structure 110. The sealant 151 may extend along a sidewall of the first semiconductor chip 120 and may surround the sidewall of the first semiconductor chip 120. In some implementations, the sealant 151 may cover an upper surface 129 of the first semiconductor chip 120, e.g., the upper surface 129 of the first semiconductor chip 120 that faces the metal plate 170. In this regard, an upper surface of the sealant 151 may be arranged at a higher vertical level than the upper surface 129 of the first semiconductor chip 120 (see FIG. 1A). In some implementations, a metal plate 170 may be arranged on the upper surface 129 of the first semiconductor chip 120 through an adhesive 180 without the sealant 151 (see FIGS. 1B and 1D), or the metal plate 170 may be arranged directly on the upper surface 129 of the first semiconductor chip 120 without the adhesive 180 (see FIG. 1C). Furthermore, the sealant 151 may fill a gap between the first semiconductor chip 120 and the first redistribution structure 110 and may surround sidewalls of the first chip connection bumps 143. The sealant 151 may extend along a sidewall of the second semiconductor chip 130 and may surround the sidewall of the second semiconductor chip 130. In some implementations, the sealant 151 may cover an upper surface of the second semiconductor chip 130, and the upper surface of the sealant 151 may be arranged at a vertical level higher than the upper surface of the second semiconductor chip 130. Furthermore, the sealant 151 may fill a gap between the second semiconductor chip 130 and the first redistribution structure 110 and may surround sidewalls of the second chip connection bumps 145.

For example, the sealant 151 may include epoxy-based molding resin or polyimide-based molding resin. In some implementations, the sealant 151 may include a high-k epoxy molding compound.

Connection structures 160 (see FIGS. 1A, 1C, and 1D) and 160a (see FIG. 1B) may include a polymer-based material. To attach the connection structures 160 (see FIGS. 1A, 1C, and 1D) and 160a (see FIG. 1B) to the first redistribution structure 110, an adhesive may be applied to the first redistribution structure 110 before mounting the connection structures 160 (see FIGS. 1A, 1C, and 1D) and 160a (see FIG. 1B) thereon.

The metal plate 170 may include Cu. The metal plate 170 may not be in direct contact with the semiconductor chips 120 and 130. Referring to FIG. 1A, when the connection structure 160 is formed in a tower shape, the metal plate 170 may be arranged apart from the first semiconductor chip 120 with the sealant 151 therebetween. Referring to FIG. 1B, when the connection structure 160a is formed in a bridge shape not in contact with the first redistribution structure 110, the metal plate 170 may be arranged on the first semiconductor chip 120 through the adhesive 180 applied on the first semiconductor chip 120. Referring to FIG. 1C, the connection structure 160 may be formed in a tower shape, but unlike FIG. 1A, the first semiconductor chip 120 may be in direct contact with the metal plate 170. Referring to FIG. 1D, the connection structure 160 may be formed in a tower shape, but unlike FIG. 1A, the metal plate 170 may be arranged on the upper surface 129 of the first semiconductor chip 120 with the adhesive 180 therebetween.

In this regard, in FIGS. 1B and 1D, the adhesive 180 applied on the first semiconductor chip 120 may include a thermal interconnection material (TIM).

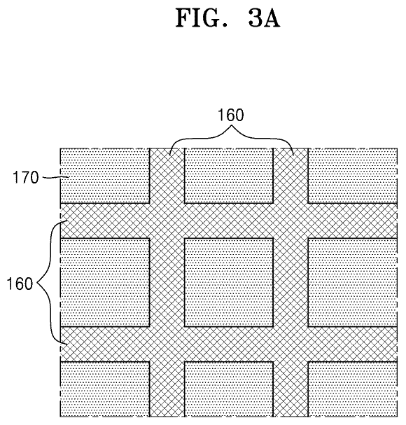

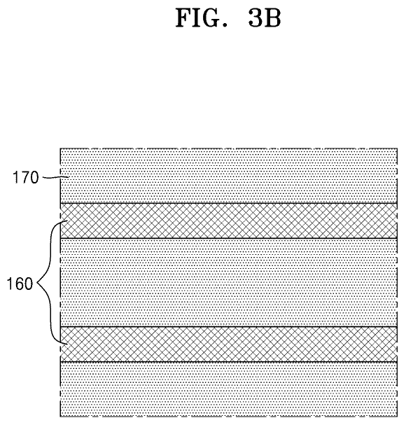

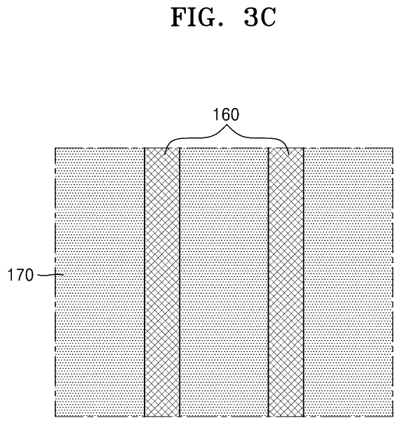

The connection structures 160 (see FIGS. 1A, 1C, and 1D) and 160a (see FIG. 1B) and the metal plate 170 will be described in detail below with reference to FIGS. 3A to 3C.

Hereinafter, a method of manufacturing the semiconductor device 10 of FIG. 1A will be described with reference to FIGS. 2A to 2F.

Referring to FIG. 2A, the first redistribution structure 110 is formed on a carrier substrate CA. The first redistribution structure 110 may include the plurality of first redistribution insulating layers 111 sequentially stacked on the carrier substrate CA, and the first conductive redistribution pattern 113 insulated by the plurality of first redistribution insulating layers 111. The first conductive redistribution pattern 113 may include the external connection pad 1135 extending along an upper surface of the carrier substrate CA, the first conductive layers 1131 extending along upper surfaces of the plurality of first redistribution insulating layers 111, and a conductive via pattern 1133 extending through one of the plurality of first redistribution insulating layers 111.

To form the first redistribution structure 110, the external connection pad 1135 may first be formed on the carrier substrate CA. The external connection pad 1135 may be formed through a plating process. For example, after the seed metal layer 115 is formed on the carrier substrate CA, a plating process using the seed metal layer 115 may be performed to form the external connection pad 1135. After the external connection pad 1135 is formed, a first operation of forming an insulating film covering the external connection pad 1135 and having a via hole, and a second operation of forming the first conductive via pattern 1133 filling the via hole of the insulating film and the first conductive layer 1131 extending along an upper surface of the insulating film may be performed. The second operation of forming the first conductive via pattern 1133 and the first conductive layer 1131 may include a plating process using the seed metal layer 115. Thereafter, the first operation of forming the insulating film and the second operation of forming the first conductive layer 1131 may be repeated several times to form the first redistribution structure 110 having a multi-layer wiring structure.

Referring to FIG. 2B, the first semiconductor chip 120 and the second semiconductor chip 130 are mounted on the first redistribution structure 110. The first semiconductor chip 120 and the second semiconductor chip 130 may be mounted on the first redistribution structure 110 by, for example, a flip chip method.

Referring to FIGS. 2C and 2D, a structure to which the connection structure 160 and the metal plate 170 are attached is attached to the first redistribution structure 110. The connection structure 160 may include a polymer-based material, and the metal plate 170 may include Cu. Before proceeding with the process of FIG. 2C, an adhesive may be applied to the upper surface of the first redistribution structure 110 at a location where the connection structure 160 is to be attached. Because the connection structure 160 is formed in a tower shape, the metal plate 170 may be arranged apart from the first and second semiconductor chips 120 and 130 at a certain interval without being in direct contact with the same. A horizontal pattern formed by the connection structure 160 and the metal plate 170 will be described below with reference to FIGS. 3A to 3C.

Next, referring to FIG. 2E, the sealant 151 may be formed on the first redistribution structure 110 to fill spaces between the first semiconductor chip 120, the second semiconductor chip 130, the connection structure 160, and the metal plate 170. For example, the sealant 151 fills first spaces defined by lower surfaces of the metal place 170 that face the first redistribution structure 110, the sidewalls of the connection structures 160 that face the first and second semiconductor chips 120 and 130, and upper surfaces of the first and second semiconductor chips 120 and 130 that face the metal plates 170. To form the sealant 151, a liquid molding material may be supplied onto the carrier substrate CA, and then, the molding material may be hardened. In some implementations, the molding material may include a high-k epoxy molding compound. After the process of forming the sealant 151 is completed, the carrier substrate CA may be removed from the first redistribution structure 110 (see FIG. 2F).

Referring to FIG. 2F, the result of FIG. 2E may be cut along a cutting line SL. Through the cutting process, the result of FIG. 2E may be separated into multiple packages. In some implementations, the cutting line SL may be a line formed vertically across the connection structure 160. In some implementations, the cutting line SL may be a scribe lane. In some implementations, the cutting process may be performed through a blade sawing process. When the process of FIG. 2F of separating the resulting semiconductor package into multiple packages is completed, the semiconductor device 10 shown in FIG. 1A may be obtained.

FIGS. 3A to 3C are horizontal cross-sectional views illustrating examples of arrangement patterns of the connection structure 160 and the metal plate 170.

First, referring to FIG. 3A, the connection structure 160 is formed to have a grid pattern in a plan view, e.g., along the vertical direction (e.g., a Z direction). The metal plate 170 may be formed in a rectangular shape that fills the inside of the grid pattern. A thickness of the metal plate 170 in the Z direction may be the same as a thickness of the connection structure 160 in the Z direction. That is, an upper surface of the metal plate 170 may be coplanar with an upper surface of the connection structure 160.

In some implementations, horizontal lines and/or vertical lines forming the pattern of the connection structure 160 may be spaced apart from each other at the same interval. In some implementations, the horizontal lines and/or vertical lines forming the pattern of the connection structure 160 may be spaced apart from each other at different intervals. In some implementations, the horizontal lines and/or vertical lines forming the pattern of the connection structure 160 may have the same width. In some implementations, the horizontal lines and/or vertical lines forming the pattern of the connection structure 160 may have different widths.

The connection structure 160 may be formed so as not to overlap the first and second semiconductor chips 120 and 130 in a plan view. This is because, referring to FIG. 2F, the semiconductor package may be cut through the connection structure 160 and separated into multiple packages. Each metal plate 170 surrounded by the connection structure 160 may be formed to a size that completely covers upper surfaces of the first and second semiconductor chips 120 and 130 in a plan view. That is, in some implementations, a size of a horizontal cross-sectional area of the metal plate 170 is greater than or equal to sizes of the upper surfaces of the first and second semiconductor chips 120 and 130.

Referring to FIGS. 3B and 3C, the connection structure 160 can also be formed in a line pattern facing a specific direction. In FIG. 3B, the pattern of the connection structure 160 may include horizontal lines. In this regard, a length of the metal plate 170 in the vertical direction is greater than or equal to lengths of edges of the first and second the semiconductor chips 120 and 130. In FIG. 3C, the pattern of the connection structure 160 may include vertical lines. In this regard, a length of the metal plate 170 in the horizontal direction may not be less than lengths of edges of the first and second the semiconductor chips 120 and 130.

In FIGS. 3B and 3C, like in FIG. 3A, line patterns constituting the connection structure 160 are spaced apart from each other at the same interval or different intervals. In addition, the line patterns constituting the connection structure 160 may have the same width or different widths.

FIGS. 3A to 3C illustrate examples of patterns that may be formed by the connection structure 160, but the present disclosure is not limited thereto, and the connection structure 160 may be formed in other types of line patterns.

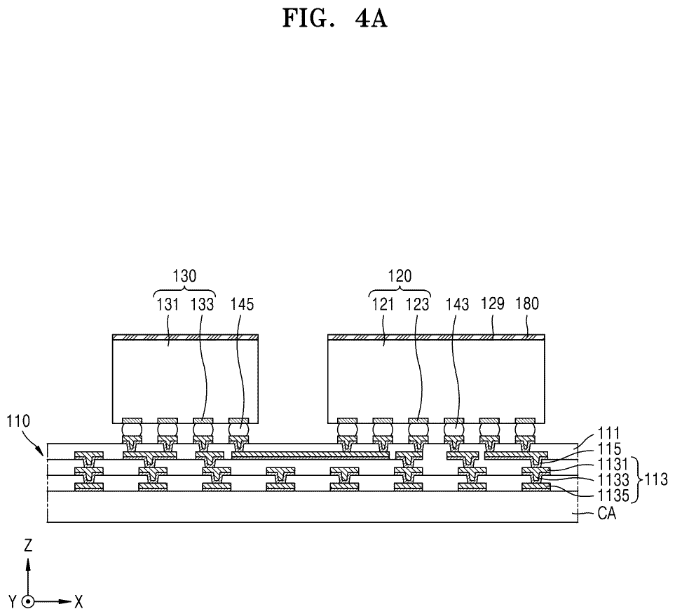

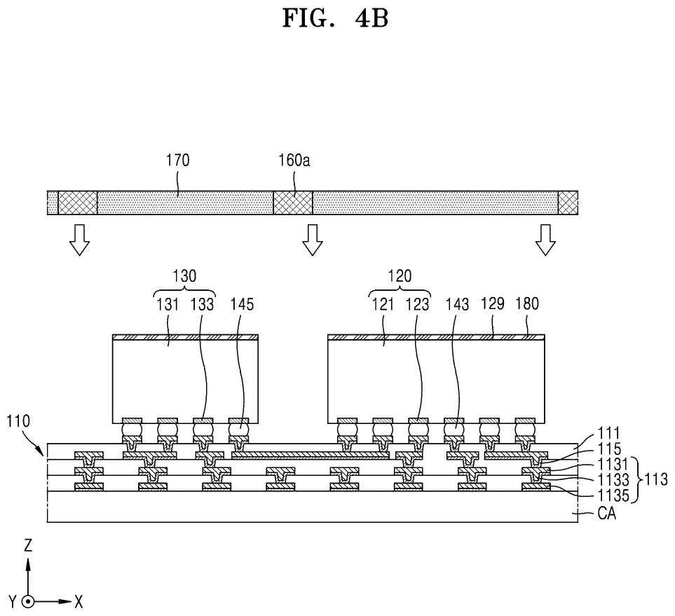

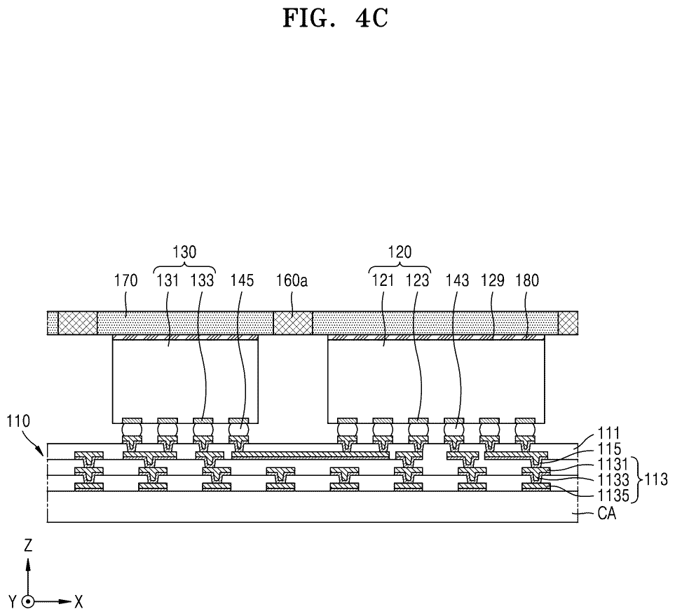

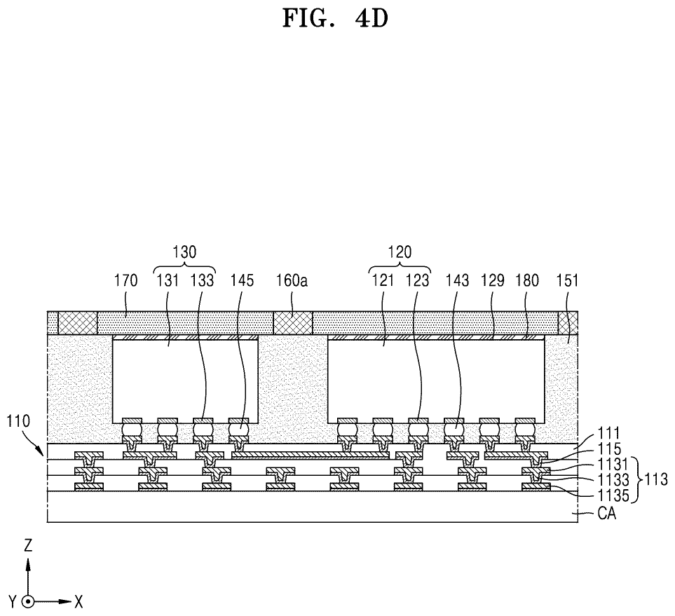

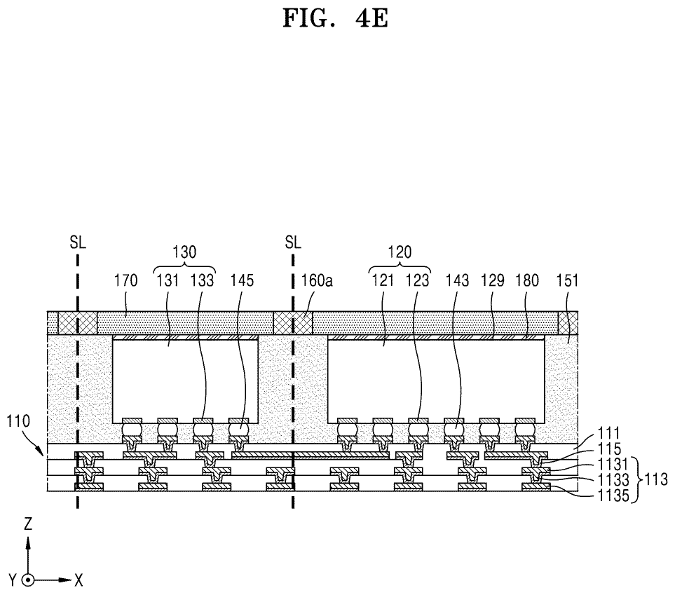

Hereinafter, a method of manufacturing the semiconductor device 20 of FIG. 1B will be described with reference to FIGS. 4A to 4E. Descriptions that are the same as those provided above with respect to the method of manufacturing the semiconductor device 10 will be omitted, and differences will be mainly described below.

First, referring to FIGS. 2A and 2B, an initial process for manufacturing the semiconductor device 20 may be performed in the same manner as the initial process for manufacturing the semiconductor device 10. Next, referring to FIGS. 4A, 4B, and 4C together, the adhesive 180 may be thinly applied on the first and second semiconductor chips 120 and 130 in the result of FIG. 2B (see FIG. 4A). Because the connection structure 160a included in the semiconductor device 20 (see FIG. 1B) is formed in a bridge shape rather than a tower shape, unlike the semiconductor device 10 described above, after the adhesive 180 is applied to the upper surfaces of the first and second semiconductor chips 120 and 130, a structure including the metal plate 170 and the connection structure 160a may be mounted on the adhesive 180 (see FIGS. 4B and 4C). The connection structure 160a may include a polymer-based material, and the metal plate 170 may include Cu. A horizontal pattern formed by the connection structure 160 and the metal plate 170 may be understood with reference to FIGS. 3A to 3C.

Referring to FIG. 4D, the sealant 151 may be formed on the first redistribution structure 110 to fill spaces between the first semiconductor chip 120, the second semiconductor chip 130, the connection structure 160, and the metal plate 170. To form the sealant 151, a liquid molding material may be supplied onto the carrier substrate CA, and then, the molding material may be hardened. In some implementations, the molding material may include a high-k epoxy molding compound. After the process of forming the sealant 151 is completed, the carrier substrate CA may be removed from the first redistribution structure 110 (see FIG. 4E).

Referring to FIG. 4E, the result of FIG. 4D may be cut along the cutting line SL. Through the cutting process, the result of FIG. 4D may be separated into multiple packages. In some implementations, the cutting line SL may be a line formed vertically across the connection structure 160a. In some implementations, the cutting line SL may be a scribe lane. In some implementations, the cutting process may be performed through a blade sawing process. When the process of FIG. 4E of separating the resulting semiconductor package into multiple packages is completed, the semiconductor device 20 shown in FIG. 1B may be obtained.

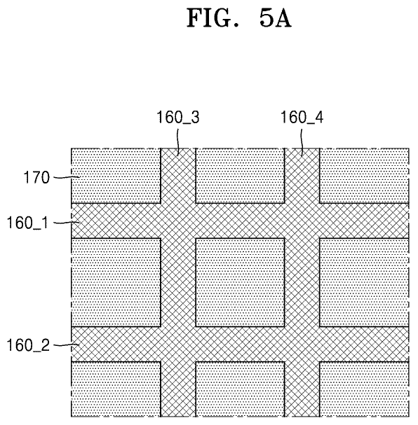

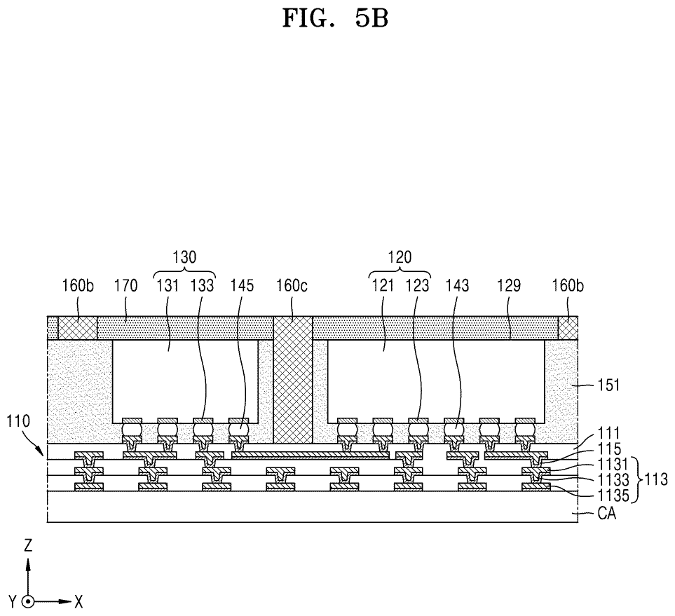

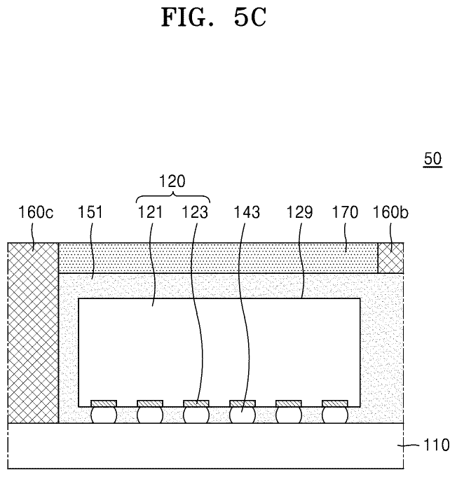

FIG. 1A illustrates the semiconductor device 10 including the connection structure 160 having a tower shape, and FIG. 1B illustrates the semiconductor device 20 including the connection structure 160a having a bridge shape. The semiconductor device 30 of FIG. 1C and the semiconductor device 40 of FIG. 1D are modified examples of the semiconductor device 10 of FIG. 1A, wherein the semiconductor device is formed to include the connection structure 160 having a tower shape, and wherein the first semiconductor chip 120 is in direct contact with the metal plate (see semiconductor device 30 of FIG. 1C), or the adhesive 180 is applied between the first semiconductor chip 120 and the metal plate 170 (see semiconductor device 40 of FIG. 1D). Hereinafter, a semiconductor device 50 including hybrid connection structures 160b and 160c in which the above types are mixed will be described with reference to FIGS. 5A to 5C.

FIG. 5A is a horizontal cross-sectional view illustrating an example of an arrangement pattern of a connection structure and a metal plate of the present disclosure. FIGS. 5B and 5C are vertical cross-sectional views schematically illustrating the semiconductor device 50.

First, referring to FIG. 5A, like in FIG. 3A, a connection structure may be formed in a grid pattern including a plurality of horizontal line patterns, that is, first and second line patterns 160_1 and 160_2, and a plurality of vertical line patterns, that is, third and fourth line patterns 160_3 and 160_4. In addition, a plurality of metal plates 170 may be filled inside the grid pattern.

Because FIG. 5A includes a hybrid connection structure, at least some of the first to fourth line patterns 160_1 to 160_4 constituting the grid pattern may be formed to have the same thickness as the metal plate 170. The remaining ones of the first to fourth line patterns 160_1 to 160_4 constituting the grid pattern may be formed in a tower shape having an upper surface arranged at the same vertical level as the upper surface of the metal plate 170, and a lower surface having a protrusion in the direction of the first redistribution structure 110 so as to be in contact with the first redistribution structure 110.

In some implementations, the first line pattern 160_1 may be formed as a tower-shaped connection structure, and the second, third, and fourth line patterns 160_2, 160_3, and 160_4, may be formed as bridge-shaped connection structures. In some implementations, the first and second line patterns 160_1 and 160_2 may be formed as tower-shaped connection structures, and the third and fourth line patterns 160_3 and 160_4 may be formed as bridge-shaped connection structures. However, this is merely an example configuration, and possible combinations are not limited to those listed herein.

A vertical cross-sectional view of the semiconductor device 30 including the hybrid connection structure described above may be understood with reference to FIGS. 5B and 5C. The semiconductor device 50 of FIG. 5B may include both the connection structure 160b having a bridge shape and the connection structure 160c having a tower shape. In FIG. 5B, the sealant 151 including a high-k epoxy molding compound is formed to fill spaces between the first semiconductor chip 120, the second semiconductor chip 130, the connection structures 160b and 160c, and the metal plate 170 on the first redistribution structure 110. For example, a first space filled by sealant 151 is defined by the lower surfaces of the metal plates 170, the sidewalls of the first and second semiconductor chips 120 and 130, a lower surface of the connection structure 160b and a side surface of the connection structure 160c. Then, the carrier substrate CA may be separated from the first redistribution structure 110, and the resulting semiconductor package may be cut through the connection structures 160b and 160c to be separated into multiple packages, thereby obtaining the result of FIG. 5C. Referring to the semiconductor device 50 of FIG. 5C, the connection structure 160c having a tower shape may be arranged on one sidewall surrounding the first semiconductor chip 120, and the connection structure 160b having a bridge shape may be arranged on the other sidewall surrounding the first semiconductor chip 120.

The semiconductor devices 10, 20, 30, 40, and 50 may include a structure including the connection structures 160, 160a, 160b, and 160c and the metal plate 170, and thus, the amount of a high-k epoxy molding compound used may be reduced. Also, due to the characteristics of the connection structures 160, 160a, 160b, and 160c including a polymer-based material, ease in performing a sawing process may be expected. In addition, by varying thicknesses, widths, and heights of the connection structures 160, 160a, 160b, and 160c according to user demands, improvement in warpage may be expected.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to embodiments thereof, it will be understood that various changes in form and details may be made therein without departing from the spirit and scope of the following claims.

What is claimed is:

1. A semiconductor device comprising:
a package substrate;
a semiconductor chip stacked on the package substrate along a vertical direction;
a connection structure arranged on the package substrate and comprising an inner surface that surrounds a sidewall of the semiconductor chip;
a metal plate attached to the inner surface of the connection structure; and
a sealant covering an upper surface of the semiconductor chip that faces the metal plate and in contact with a side surface of the connection structure.

2. The semiconductor device of claim 1, wherein the metal plate comprises copper.

3. The semiconductor device of claim 1, wherein each side surface of the connection structure does not overlap a side surface of the semiconductor chip in the vertical direction.

4. The semiconductor device of claim 1, wherein a lower surface of the metal plate is arranged at a vertical level higher than the upper surface of the semiconductor chip.

5. The semiconductor device of claim 1, wherein an internal space defined by the connection structure surrounding the semiconductor chip has a rectangular shape in a plan view.

6. The semiconductor device of claim 5, wherein a horizontal area of the rectangular shape is greater than a horizontal area of the semiconductor chip.

7. The semiconductor device of claim 1, wherein the sealant is formed to fill between the semiconductor chip and the metal plate in an internal space defined by the connection structure.

8. The semiconductor device of claim 1, wherein the sealant comprises an epoxy molding compound.

9. The semiconductor device of claim 1, further comprising chip connection bumps between a chip pad of the semiconductor chip and the package substrate,
wherein the sealant is between the semiconductor chip and the package substrate and is in contact with the chip connection bumps.

10. A semiconductor device comprising:
a package substrate;
a semiconductor chip stacked on the package substrate in a vertical direction;
a connection structure arranged parallel to and spaced apart from the semiconductor chip, at a vertical level higher than an upper surface of the semiconductor chip, and having line patterns in a plan view along the vertical direction, wherein the upper surface of the semiconductor chip is opposite a lower surface of the semiconductor chip that faces the package substrate;
a metal plate between the line patterns of the connection structure, wherein the metal plate comprises a lower surface facing the semiconductor chip; and
a sealant that fills a first space defined by the lower surface of the metal plate, a sidewall of the connection structure that faces the semiconductor chip, and the upper surface of the semiconductor chip, wherein the sealant further fills a second space between the package substrate and the semiconductor chip.

11. The semiconductor device of claim 10, wherein the metal plate comprises copper.

12. The semiconductor device of claim 10, wherein the connection structure does not overlap the semiconductor chip in a plan view along the vertical direction.

13. The semiconductor device of claim 10, wherein a vertical thickness of the connection structure is the same as a vertical thickness of the metal plate.

14. The semiconductor device of claim 10, wherein a horizontal area of the metal plate is greater than a horizontal area of the semiconductor chip.

15. The semiconductor device of claim 10, wherein the sealant comprises an epoxy molding compound.

16. The semiconductor device of claim 10, wherein the line patterns comprise grid patterns.

17. A semiconductor device comprising:
a package substrate;
a semiconductor chip stacked on the package substrate in a vertical direction;
a first connection structure arranged on the package substrate, a sidewall of the first connection structure contacting at least one edge of a sidewall of the semiconductor chip, and having a height greater than a height of the semiconductor chip along the vertical direction;
a second connection structure having a lower surface in contact with an upper surface of the first connection structure and having line patterns in a plan view along the vertical direction;
a metal plate between the line patterns of the second connection structure; and
a sealant filling a first space defined by the sidewall of the first connection structure, a lower surface of the second connection structure facing the package substrate, a lower surface the metal plate facing the semiconductor chip, and the sidewall of the semiconductor chip, wherein the sealant further fills a second space defined by an upper surface the package substrate facing the semiconductor chip and a lower surface of the semiconductor chip facing the package substrate,
wherein the first connection structure and the second connection structure are formed as a single body.

18. The semiconductor device of claim 17, wherein the metal plate comprises copper, and
a horizontal area of the metal plate is greater than a horizontal area of the semiconductor chip.

19. The semiconductor device of claim 17, wherein the second connection structure does not overlap the semiconductor chip in a plan view.

20. The semiconductor device of claim 17, wherein the line patterns comprise grid patterns.
